(19) United States
(12) Patent Application Publication
(10) Pub. No.: US 2013/0061907 A1
(43) Pub. Date: Mar. 14, 2013

(54) PORTABLE SOLAR ENERGY CURTAIN WITH PHOTOELECTRIC CONVERSION

(71) Applicant: CHAU-SYWAN WANG, KAOHSIUNG CITY (TW)

(72) Inventor: CHAU-SYWAN WANG, KAOHSIUNG CITY (TW)

(21) Appl. No.: 13/590,304

(22) Filed: Aug. 21, 2012

(30) Foreign Application Priority Data
Sep. 8, 2011 (TW) 100216915

(51) Int. Cl. H01L 31/052; H01L 31/045

(52) U.S. Cl. 136/245; 136/248

(57) ABSTRACT

The invention relates to a portable solar energy curtain with photoelectric conversion, which provides an easy-carried and easy-expanded structure and a photoelectric conversion circuit combined with a design of a plurality of thermoelectric cooling chips for efficiently helping indoor or car-inner heating or cooling. The present invention provides appropriate cold air for cooling the temperature inside the cars and keeping at room temperature when the cars stop with doors closed. Further, the present invention provides cold air or hot air at anytime and anywhere for keeping tents or indoor spaces in the better temperature state. Therefore, the present invention is easy to use and carry without energy consumption.

### BACKGROUND OF THE INVENTION

1. Field of the Invention

The invention relates to a portable solar energy curtain with photoelectric conversion, and more particularly to a thermoelectric cooling chip which uses solar energy as an energy source to efficiently help indoor or car-inner heating or cooling.

2. Description of the Related Art

Nowadays, global warming leads to increasingly high temperature in some areas. Therefore, when the car stops with doors closed and the internal air conditioning system stops running, the inside temperature will be higher than the outside temperature after a period of time. As a result, it cannot be seated for the high temperature inside the car, causing a disturbance in our daily life.

The same situation also occurs when staying at home or going camping. Due to the prolonged exposure to sunlight, the temperature in the tent or house is high like an oven. After going home, people have to turn on the air conditioning for a period of time to reduce indoor temperature, causing another disturbance in our daily life.

Moreover, it is colder and colder in some areas for climate change. Freeze to death accidents frequently take place if there is no heating device in the cold area. Even if there is heating device, it is useless without electric power or power sources; that is, electrical power is required for producing cold air or hot air. However, it is not easy to get electrical power while being far away from home or being in remote areas.

Solar energy is inexhaustible energy so it should be fully utilized. Although there are a lot of relative devices provide solar panels to absorb solar energy and then convert light energy into electrical energy, these devices are complicated and are not easy to carry. Therefore, there is room for improvement.

### SUMMARY OF THE INVENTION

It is a primary object of the present invention to provide a portable solar energy curtain with photoelectric conversion, which provides an easy-carried and easy-expanded structure and a photoelectric conversion circuit combined with a design of a plurality of thermoelectric cooling chips for efficiently helping indoor or car-inner heating or cooling.

In order to achieve the above object, the invention comprises: an outer layer made of insulated material and having a first surface and an opposite side as a second surface; a plurality of solar cells mounted on the first surface of the outer layer and each of the solar cells connected in series or series-parallel circuit; an inner layer made of insulated material and having a third surface and an opposite side as a fourth surface; a photoelectric conversion circuit mounted between the second surface of the outer layer and the third surface of the inner layer for converting light energy from the solar cells into electrical energy to provide required power for the inner layer; and a plurality of thermoelectric cooling chips mounted on the fourth surface of the inner layer and having a heating/cooling setting function provided for the inner layer distributing a high or low temperature after receiving the required power from the photoelectric conversion circuit to form a portable solar energy curtain.

Base on the features disclosed, the present invention provides appropriate cold air for cooling the temperature inside the cars and keeping at room temperature when the cars stop with doors closed. Further, the present invention provides cold air or hot air at anytime and anywhere for keeping tents or indoor spaces in the better temperature state. Therefore, the present invention is easy to use and carry without energy consumption.

### BRIEF DESCRIPTION OF THE DRAWINGS

FIG. 1 is a perspective view of an outer side surface of the present invention;

FIG. 2 is a perspective view of an inner side surface of the present invention;

FIG. 3 is a structure schematic view of the present invention;

FIG. 4 is an exploded view of a thermoelectric cooling chip structure of the present invention;

FIG. 5 is an exploded view of a thermoelectric cooling chip structure of the present invention;

FIG. 6 is the first application example of the present invention;

FIG. 7 is the second application example of the present invention; and

FIG. 8 is the third application example of the present invention.

### DETAILED DESCRIPTION OF THE PREFERRED EMBODIMENT

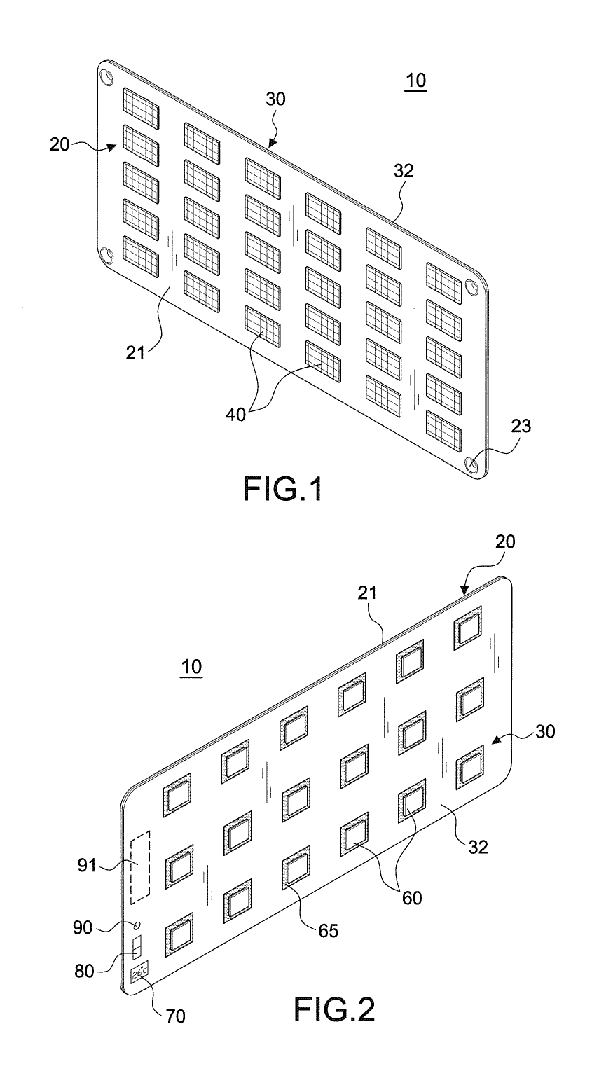

Referring to FIGS. 1 through 8, the preferred embodiment of a portable solar energy curtain with photoelectric conversion in accordance with the present invention comprises: an outer layer 20, an inner layer 30, a plurality of solar cells 40, a photoelectric conversion circuit 50, and a plurality of thermoelectric cooling chips 60.

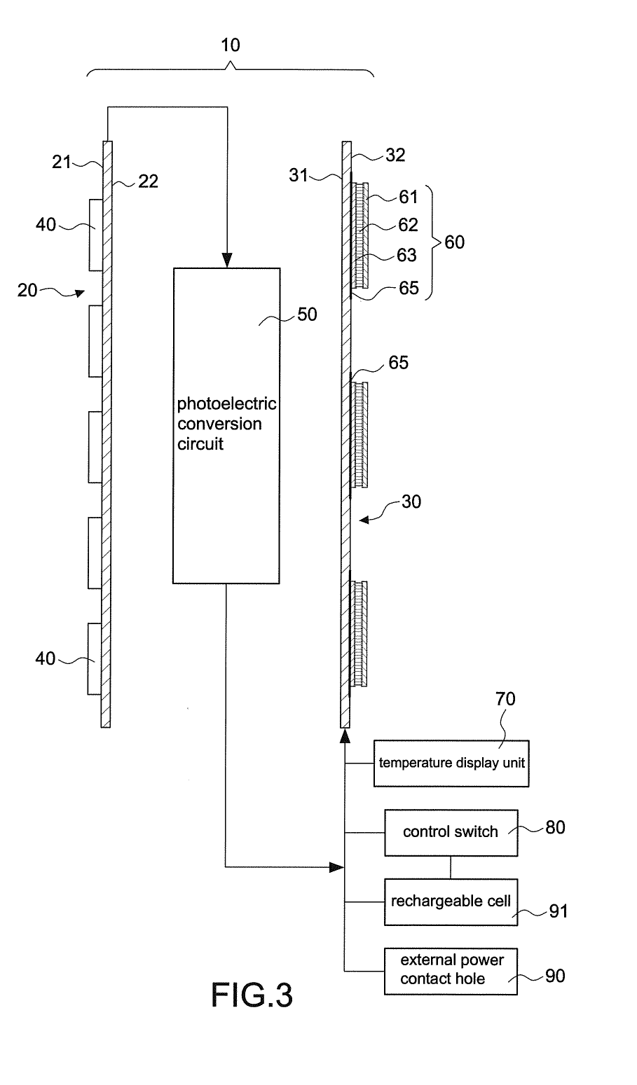

The outer layer 20 made of insulated material has a first surface 21 and an opposite side as a second surface 22 and the inner layer 30 made of insulated material has a third surface 31 and an opposite side as a fourth surface 32. The plurality of solar cells 40 as shown in FIG. 3 are mounted on the first surface 21 of the outer layer 20 and each of the solar cells 40 is connected in series or series-parallel circuit. In this embodiment, the solar cells 40 may include single crystal silicon, poly-silicon, amorphous silicon or film type but it is not a limitation.

With the reference to FIG. 3, the photoelectric conversion circuit 50 is mounted between the second surface 22 of the outer layer 20 and the third surface 31 of the inner layer 30 for converting light energy from the solar cells 40 into electrical energy and providing required power for the inner layer 30, and the plurality of thermoelectric cooling chips 60 are mounted on the fourth surface 32 of the inner layer 30 and have a heating/cooling setting function provided for the inner layer 30 distributing a high or low temperature after receiving the required power from the photoelectric conversion circuit 50 in order to form a solar energy curtain 10. In this embodiment, the solar energy curtain 10 is a winding and flexible body.

Further, the fourth surface 32 of the inner layer 30 of the solar energy curtain 10 includes a temperature display unit 70, a control switch 80, and an external power contact hole 90. When the solar energy is insufficient, the fourth surface 32 may connect to the supply mains to provide required power for the plurality of thermoelectric cooling chips 60. Moreover, a rechargeable cell 91 is arranged between the inner layer 30 and the outer layer 20 of the solar energy curtain 10 for electrically connecting to the control switch 80. Therefore, when the solar energy is insufficient, the present invention may provide required power from the rechargeable cell 91.

Further, the first surface 21 of the outer layer 20 of the solar energy curtain 10 has a plurality of positioning elements 35. In this embodiment, the positioning elements may include suction disks, Velcro bands, hooks or ropes but it is not a limitation. Moreover, a heat dissipating pad 65 mounted between a bottom surface of the thermoelectric cooling chip 60 and the fourth surface 32 of the inner layer 30 is provided for increasing heat dissipating efficiency.

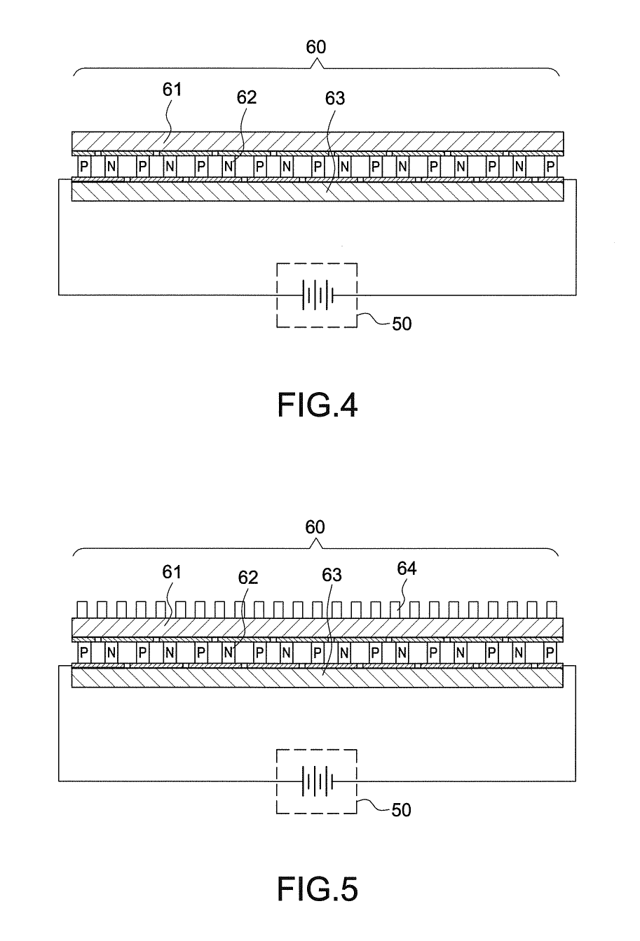

With the reference to FIGS. 4 and 5, the thermoelectric cooling chip 60 includes a first substrate 61, a second substrate 63, multiple P-type or N-type semiconductor ships 62 between the first substrate 61 and the second substrate 63. The thermoelectric cooling chip 60 has a heating or cooling reaction according to a predetermined direction of a current to produce a temperature difference between the first substrate 61 and the second substrate 63 for efficiently helping indoor or car-inner heating or cooling. Moreover, the first substrate 61 includes a heat sink 64 on a surface thereof.

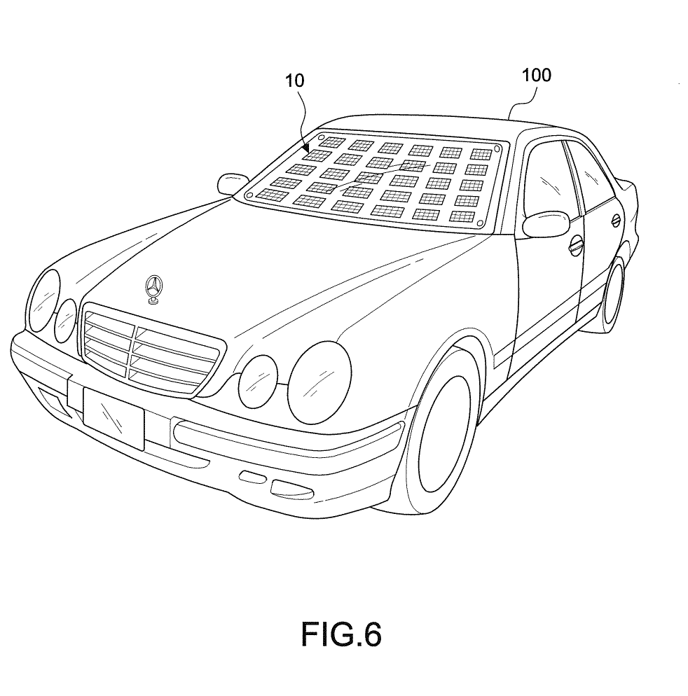

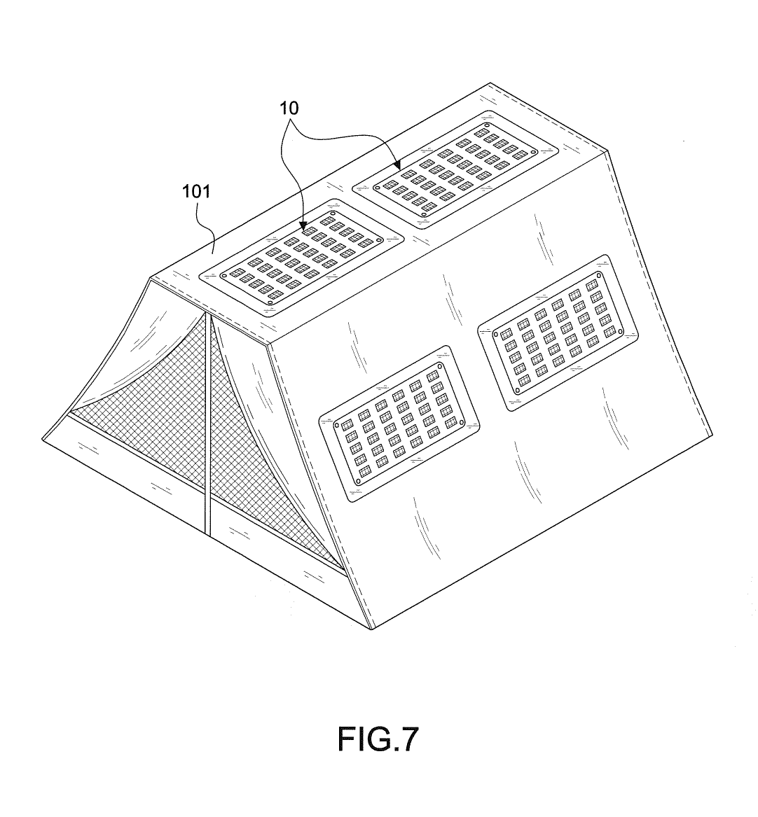

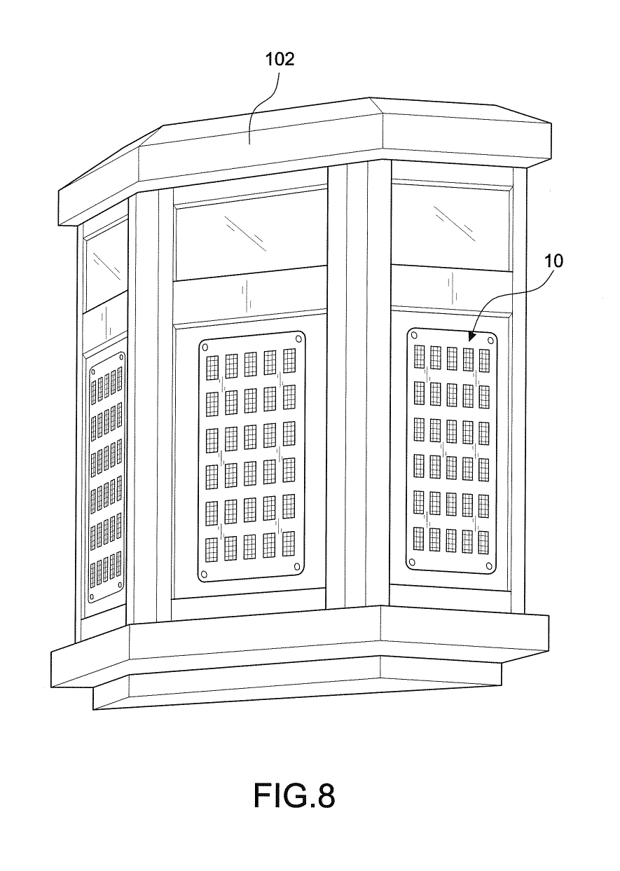

FIG. 6 is a schematic view of the present invention applying to a car 100; FIG. 7 is a schematic view of the present invention applying to a tent 101; FIG. 8 is a schematic view of the present invention applying indoors 102. However, the disclosed application examples are not limitations.

Based on the application examples disclosed, the present invention is not only a sunshade curtain but a portable solar energy curtain with photoelectric conversion, which provides the outer layer for absorbing solar energy, the photoelectric conversion circuit for converting the light energy into the electrical energy and the inner layer for heating or cooling, being convenience to carry and store.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A portable solar energy curtain with photoelectric conversion, comprising:
an outer layer made of insulated material and having a first surface and an opposite side as a second surface;
a plurality of solar cells mounted on the first surface of the outer layer and each of the solar cells connected in series or series-parallel circuit;
an inner layer made of insulated material and having a third surface and an opposite side as a fourth surface;
a photoelectric conversion circuit mounted between the second surface of the outer layer and the third surface of the inner layer for converting light energy from the solar cells into electrical energy to provide required power for the inner layer; and
a plurality of thermoelectric cooling chips mounted on the fourth surface of the inner layer and having a heating/cooling setting function provided for the inner layer distributing a high or low temperature after receiving the required power from the photoelectric conversion circuit to form a solar energy curtain.

2. The portable solar energy curtain with photoelectric conversion as claimed in claim 1, wherein the solar energy curtain is a winding and flexible body.

3. The portable solar energy curtain with photoelectric conversion as claimed in claim 1, wherein the fourth surface of the inner layer of the solar energy curtain includes a temperature display unit, a control switch, and an external power contact hole.

4. The portable solar energy curtain with photoelectric conversion as claimed in claim 3, further comprising a rechargeable cell arranged between the inner layer and the outer layer of the solar energy curtain for electrically connecting to the control switch.

5. The portable solar energy curtain with photoelectric conversion as claimed in claim 1, wherein the first surface of the outer layer of the solar energy curtain has a plurality of positioning elements including suction disks, Velcro bands, hooks or ropes.

6. The portable solar energy curtain with photoelectric conversion as claimed in claim 1, further comprising a heat dissipating pad mounted between a bottom surface of the thermoelectric cooling chip and the fourth surface of the inner layer.

7. The portable solar energy curtain with photoelectric conversion as claimed in claim 6, wherein the thermoelectric cooling chip includes a first substrate, a second substrate, multiple P-type or N-type semiconductor ships between the first substrate and the second substrate; the thermoelectric cooling chip has a heating or cooling reaction according to a predetermined direction of a current to produce a temperature difference between the first substrate and the second substrate for efficiently helping indoor or car-inner heating or cooling.

8. The portable solar energy curtain with photoelectric conversion as claimed in claim 7, wherein the first substrate includes a heat sink on a surface thereof.
